(19) United States
(12) Patent Application Publication
(10) Pub. No.: US 2025/0358927 A1
(43) Pub. Date: Nov. 20, 2025

(54) CIRCUIT BOARD STRUCTURE AND METHOD FOR MANUFACTURING THE SAME

(71) Applicant: Unimicron Technology Corp., Taoyuan City (TW)

(72) Inventors: Chih-Chiang LU, Taoyuan City (TW); Yi-Pin LIN, Taoyuan City (TW); Chi-Min CHANG, Taoyuan City (TW)

(21) Appl. No.: 18/797,476

(22) Filed: Aug. 7, 2024

(30) Foreign Application Priority Data
May 17, 2024 (TW) 113118485

(51) Int. Cl. H05K 1/02; H05K 3/42; H05K 3/46

(52) U.S. Cl. CPC H05K 1/0251; H05K 1/024; H05K 3/423; H05K 3/429; H05K 3/46; H05K 2201/0195; H05K 2201/09509; H05K 2201/09809; H05K 2201/10098; H05K 2203/1461

(57) ABSTRACT

A circuit board structure includes a composite layer, a first dielectric layer, a second dielectric layer, an isolation layer, a first conductive layer, a second conductive layer, an antenna layer and a signal layer. The composite layer includes multiple dielectric layers and multiple inner wiring layers. The first dielectric layer is on the top surface of the composite layer. The second dielectric layer is on the bottom surface of the composite layer. The isolation layer is between the first and second dielectric layers. The first conductive layer is between the isolation layer and these inner wiring layers. The second conductive layer covers an inner wall of the opening. The antenna layer is located above the top surface of the second dielectric layer. The signal layer is located below the bottom surface of the first dielectric layer.

### CROSS-REFERENCE TO RELATED APPLICATION

This application claims priority to Taiwan Application Serial Number 113118485, filed May 17, 2024, which is herein incorporated by reference in its entirety.

### BACKGROUND

### Field of Invention

The present invention relates to a circuit board structure and a method for manufacturing the same.

### Description of Related Art

In existing technology, most circuit boards use plating through holes (PTH) as the conventional technology for cross-layer signal transmission. However, PTH is prone to problems such as impedance matching, energy dissipation and signal interference in high-frequency transmission. Therefore, it is not conducive to the signal integrity of the PCB high-frequency applications. Furthermore, PTH technology requires the use of multiple layers of low dielectric constant (DK)/low dissipation factor (DF) materials, thereby increasing the production cost of the circuit board. In view of this, how to provide a circuit board structure that can solve the above problems is still a goal of the research and development by those skilled in the art.

### SUMMARY

According to some embodiments of the present disclosure, a circuit board structure and a method for manufacturing the same are provided. The circuit board structure replaces the conventional PTH cross-layer signal line and the conventional antenna feeding method by coaxial vias. The present invention may transmit high frequency and high speed signals to antenna areas of antenna layers by bores. The coaxial via structure may provide transmission lines with well impedance matching, and design well-closed ground paths around vias. In addition to form well high frequency and high speed circuits, this design may separate noises and prevent the energy from dissipations. Furthermore, not all dielectric layers of this design need to use low dielectric constant (DK)/low dissipation factor (DF) materials, thereby significantly lowering the cost of materials.

According to some embodiments of the present disclosure, a circuit board structure is provided. The circuit board structure includes a composite layer, a first dielectric layer, a second dielectric layer, an isolation layer, a first conductive layer, a second conductive layer, an antenna layer and a signal layer. The composite layer includes a plurality of dielectric layers and a plurality of inner wiring layers disposed on surfaces of the dielectric layers. The first dielectric layer is on a bottom surface of the composite layer. The second dielectric layer is on a top surface of the composite layer. The isolation layer is between the first dielectric layer and the second dielectric layer, and adjacent to the composite layer, wherein the isolation layer, the first dielectric layer and the second dielectric layer jointly have an opening extending from a top surface of the second dielectric layer to a bottom surface of the first dielectric layer. The first conductive layer is between the isolation layer and the inner wiring layers, and connected to a ground portion of these inner wiring layers. The second conductive layer covers an inner well of the opening, wherein the isolation layer separates the second conductive layer from the first conductive layer, and the second conductive layer, the isolation layer and the first conductive layer form a coaxial via. The antenna layer is above the top surface of the second dielectric layer, wherein the antenna layer is connected to a top end of the second conductive layer. The signal layer is below the bottom surface of the first dielectric layer, wherein a first portion of the signal layer is connected to a bottom end of the second conductive layer.

According to some embodiments of the present disclosure, the circuit board structure described above further includes a first filler dielectric material in the opening.

According to some embodiments of the present disclosure, the circuit board structure is described above, in which a top surface of the first filler dielectric material is higher than the top surface of the second dielectric layer, and a bottom surface of the first filler dielectric material is lower than the bottom surface of the first dielectric layer.

According to some embodiments of the present disclosure, the circuit board structure is described above, in which the antenna layer covers a top surface of the first filler dielectric material, and the signal layer covers a bottom surface of the first filler dielectric material.

According to some embodiments of the present disclosure, the circuit board structure described above further includes a ground via hole penetrating through the first dielectric layer, in which the ground via hole is separated from the isolation layer, in which the ground via hole connects a second portion of the signal layer to the ground portion of the inner wiring layers.

According to some embodiments of the present disclosure, the circuit board structure is described above, in which the isolation layer has a first sidewall and a second sidewall opposite each other. The first sidewall of the isolation layer is in contact with the second conductive layer. The second sidewall of the isolation layer is in contact with the ground portion of the inner wiring layers.

According to some embodiments of the present disclosure, the circuit board structure described above further includes a second filler dielectric material in the ground via hole.

According to some embodiments of the present disclosure, the circuit board structure is described above, in which a dielectric constant of the isolation layer is lower than a dielectric constant of the dielectric layers.

According to some embodiments of the present disclosure, the circuit board structure is described above, in which the dielectric constant of the isolation layer is between 3 and 3.5.

According to some embodiments of the present disclosure, the circuit board structure is described above, in which the antenna layer has an antenna line, and the antenna line overlaps the coaxial via.

According to some embodiments of the present disclosure, the circuit board structure described above further includes a line on the top end of the second conductive layer, and configured to be connected to an antenna.

According to some embodiments of the present disclosure, a method for manufacturing a circuit board structure is provided. The method includes the following steps. A first opening is formed in a composite layer, in which the composite layer includes a plurality of dielectric layers and a plurality of inner wiring layers disposed on surfaces of the dielectric layers, and the first opening penetrates through the dielectric layers, and exposes a side surface of the dielectric layers. A first conductive layer is formed on an inner wall of the first opening, in which the first conductive layer is electrically connected to the inner wiring layers. A isolation layer is filled in the first opening. A first dielectric layer is disposed below a bottom surface of the composite layer. A signal layer is disposed below the first dielectric layer. A second dielectric layer is disposed above a top surface of the composite layer. An antenna layer is disposed on the second dielectric layer. A second opening is formed inside the first dielectric layer, the isolation layer and the second dielectric layer. A second conductive layer is formed on an inner wall of the second opening, in which the second conductive layer connects the signal layer to the antenna layer, and the second conductive layer, the isolation layer and the first conductive layer form a coaxial via.

According to some embodiments of the present disclosure, the method described above further includes the following steps. After forming the second conductive layer, the signal layer is patterned, and after forming the second conductive layer, the antenna layer is patterned.

According to some embodiments of the present disclosure, the method described above further includes the following steps. A first filler dielectric material is formed in the second opening.

According to some embodiments of the present disclosure, the method described above further includes the following steps. A ground via hole is formed inside the first dielectric layer to expose a ground portion of the inner wiring layers. A third conductive layer is formed inside the ground via hole to be connected to a ground portion of the inner wiring layers.

According to some embodiments of the present disclosure, the method described above further includes the following steps. A second filler dielectric material is formed inside the ground via hole.

### BRIEF DESCRIPTION OF THE DRAWINGS

FIG. 1A is a schematic diagram of a circuit substrate where the circuit board structure is installed in accordance with some embodiments of the present disclosure.

FIG. 1B is a partially enlarged bottom view of the circuit board structure on the circuit substrate in FIG. 1A.

FIG. 1C is a cross-sectional view of FIG. 1B taken along the line A-A′.

FIG. 1D is a top view of FIG. 1C.

FIG. 2 is a flow chart of a method for manufacturing the circuit board structure in accordance with some embodiments of the present disclosure.

FIG. 3A to FIG. 3I are cross-sectional views of a circuit board structure at various stages of the manufacture in accordance with an example of the present disclosure.

FIG. 3J is a cross-sectional view of a circuit board structure in accordance with an example of the present disclosure.

FIG. 3K is a cross-sectional view of a circuit board structure in accordance with an example of the present disclosure.

FIG. 4A is an enlarged bottom view of the dotted portion of FIG. 1A in accordance with an example of the present disclosure.

FIG. 4B is a cross-sectional view of FIG. 4A taken along the line B-B′.

FIG. 4C is a top view of FIG. 4B.

FIG. 5A to FIG. 5J are cross-sectional views of the circuit board structure of FIG. 4B at various stages of the manufacture in accordance with an example of the present disclosure.

FIG. 5K is a cross-sectional view of a circuit board structure in accordance with an example of the present disclosure.

FIG. 5L is a cross-sectional view of a circuit board structure in accordance with an example of the present disclosure.

FIG. 6 is a schematic diagram of a circuit board structure horizontally fed in an antenna in accordance with some embodiments of the present disclosure.

### DETAILED DESCRIPTION

Reference will now be made in detail to the present embodiments of the disclosure. However, it should be understood that the embodiments of the disclosure provide many practicable concepts for implementing in various subject matters. The embodiments discussed and disclosed herein are for the illustration only, and are not intended to limit the scope of the disclosure. The term “first” and “second” used herein do not indicate specific order or sequence, but are only used to distinguish the units or operations described in same technical terms.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

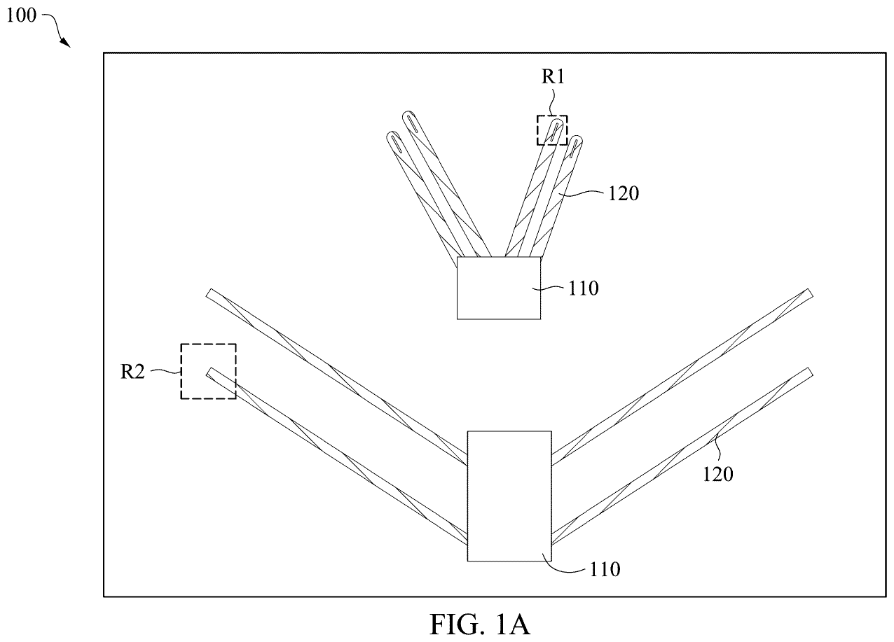

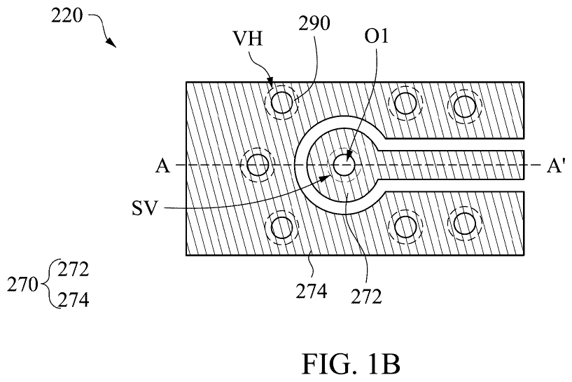

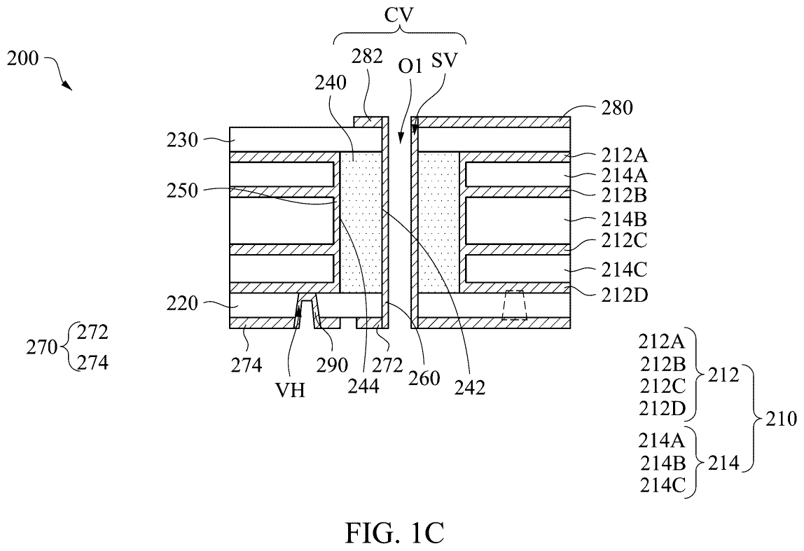

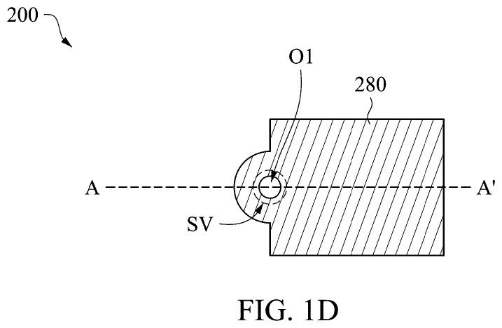

FIG. 1A is a schematic diagram of a circuit substrate where the circuit board structure is installed in accordance with some embodiments of the present disclosure. In some embodiments, the circuit substrate 100 may include a signal unit 110 and a signal line 120. The signal line 120 may transmit high-frequency and high-speed radio frequency from a receiving area R1 to the signal unit 110 or from the signal unit 110 to a transmission area R2. However, it should be noticed that the signal line 120 may be arranged in any appropriate configuration without such limitation.

FIG. 1B is a partially enlarged bottom view of the circuit board structure 200 on the receiving area R1 or the transmission area R2 of the circuit substrate 100 in FIG. 1A. FIG. 1C is a cross-sectional view of FIG. 1B taken along the line A-A′. FIG. 1D is a top view of FIG. 1C. FIG. 1B, FIG. 1C and FIG. 1D are schematic diagrams of vertically feeding methods of the circuit board structure 200. Reference is made simultaneously to FIG. 1B, FIG. 1C and FIG. 1D.

The circuit board structure 200 includes a composite layer 210, a first dielectric layer 220, a second dielectric layer 230, an isolation layer 240, a first conductive layer 250, a second conductive layer 260, a signal layer 270 and an antenna layer 280.

In some embodiments, the composite layer 210 includes plural inner wiring layers 212 and plural dielectric layers 214. In the present embodiment, the inner wiring layers 212 include inner wiring layers 212A, 212B, 212B and 212D, and the plural dielectric layers 214 include plural dielectric layers 214A, 214B and 214C, in which the number of the inner wiring layers 212 and the dielectric layers 214 may be adjusted according to the functional requirements. However, it should be noticed that the inner wiring layers 212 and the dielectric layers 214 may be arranged in any appropriate configuration without such limitation. The dielectric layers 214A, 214B and 214C may be any dielectric material. For example, in some embodiments, the dielectric layers 214A, 214B and 214C may be the polypropylene (pp), but it should be noticed that the dielectric layers 214A, 214B and 214C may adopt any appropriate dielectric materials without such limitation.

In some embodiments, the inner wiring layers 122 may be disposed on the surfaces of the dielectric layers 214. For example, in the present embodiment, the inner wiring layer 212A covers the top surface of the dielectric layer 214A. The inner wiring layer 212B cover the bottom surface of the dielectric layer 214A and the top surface of the dielectric layer 214B. The inner wiring layer 212C cover the bottom surface of the dielectric layer 214B and the top surface of the dielectric layer 214C. The inner wiring layer 212D cover the bottom surfaces of the dielectric layer 214C, and the inner wiring layers 212A, 212B, 212C and 212D are connected to each other, in which the inner wiring layers 212 have a ground portion.

In some embodiments, the first dielectric layer 220 may be on a bottom surface of the composite layer 210, and the second dielectric layer 230 may be on a top surface of the composite layer 210. The first dielectric layer 220 and the second dielectric layer 230 may be any appropriate dielectric materials. In some embodiments, the first dielectric layer 220 and the second dielectric layer 230 may be any dielectric materials with dielectric constant (DK)/dissipation factor (DF) lower than the dielectric layers 214, thereby isolating the noises during the signal transmission.

In some embodiments, the isolation layer 240 may be between the first dielectric layer 220 and the second dielectric layer 230 and adjacent to the composite layer 210. In some embodiments, the isolation layer 240 may be dielectric materials with low dielectric constant (DK)/low dissipation factor (DF). For example, the isolation layer 240 may be dielectric materials with dielectric constant (DK)/dissipation factor (DF) lower than the dielectric constant (DK)/dissipation factor (DF) of the dielectric layers 214. In some embodiments, the dielectric constant (DK) of the isolation layer 240 is between 3 and 3.5. However, it should be noticed that the isolation layer 240 may be arranged in any appropriate dielectric materials without such limitation.

Furthermore, the height and the thickness of the isolation layer 240 may be adjusted according to the functional requirements. For example, in the present embodiment, the height of the isolation layer 240 is the same as the height of the composite layer 210. In some embodiments, the thickness of the isolation layer 240 may be adjusted according to the impedance requirements of the circuit board structure 200 to provide a better isolation.

In addition, in the present embodiment, the isolation layer 240, the first dielectric layer 220 and the second dielectric layer 230 jointly have an opening O1. The opening O1 extends from the top surface of the second dielectric layer 230 to the bottom surface of the first dielectric layer 220. The opening O1 penetrates through the isolation layer 240, the first dielectric layer 220 and the second dielectric layer 230, in which the isolation layer 240 surrounds the opening O1 and is arranged in concentric circles with opening O1.

In some embodiments, the first conductive layer 250 is between the isolation layer 240 and the inner wiring layers 212, and connected to the ground portion of the inner wiring layers 212. The second conductive layer 260 covers the inner wall of the opening O1 to form a signal through via SV. The isolation layer 240 may separate the second conductive layer 260 from the first conductive layer 250, and the second conductive layer 260, the isolation layer 240 and the first conductive layer 250 forms a coaxial via CV. In detail, in the present embodiment, the isolation layer 240 has a first sidewall 242 and a second sidewall 244 opposite to each other. The first sidewall 242 of the isolation layer 240 is in contact with the second conductive layer 260. In some embodiments, the second sidewall 244 of the isolation layer 240 is in contact with the first conductive layer 250 and the ground portion of the inner wiring layers 212, so that the circuit board structure 200 have a closed ground path, in which the second conductive layer 260, the isolation layer 240 and the first conductive layer 250 are arranged in concentric circles. This design eliminates the need for the dielectric layers 214 of the composite layer 210 to specifically choose the materials with low dielectric constant (DK)/low dissipation factor (DF), thereby lowering the production cost of the circuit board structure 200.

In some embodiments, the signal layer 270 is below the bottom surface of the first dielectric layer 220, in which the signal layer 270 is available for additional processing, e.g., a photolithography process. In detail, the signal layer 270 may be patterned by the photolithography process, dividing the signal layer 270 to a first portion 272 and a second portion 274. The first portion 272 is connected to the bottom end of the second conductive layer 260, in which the first portion 272 of the signal layer 270, the antenna layer 280 and the second conductive layer 260 define a signal transmission path.

In some embodiments, the antenna layer 280 is above the top surface of the second dielectric layer 230, in which the antenna layer 280 is connected to the top end of the second conductive layer 260. The antenna layer 280 may include an appropriate antenna line 282 to form any appropriate antenna, e.g., patch antenna. However, it should be noticed that the antenna layer 280 may be arranged in any appropriate configuration without such limitation.

In some embodiments, the circuit board structure 200 further include a ground via hole VH. In the present embodiment, the ground via hole VH penetrates through the first dielectric layer 220, and the ground via hole VH is separated from the isolation layer 240, in which a third conductive layer 290 may be connected to the second portion 274 of the signal layer 270, and cover an inner wall of the ground via hole VH. The ground via hole VH connects the second portion 274 of the signal layer 270 to the ground portions of the inner wiring layers 212. The ground via hole VH, the second portion 274 of the signal layer 270 and the ground portions of the inner wiring layers 212 define a ground path, in which the ground path surrounds the transmission path. In addition, the number of the ground via holes VH may be adjusted according to the functional requirements. For example, in the present embodiment, the number of the ground via holes VH is seven.

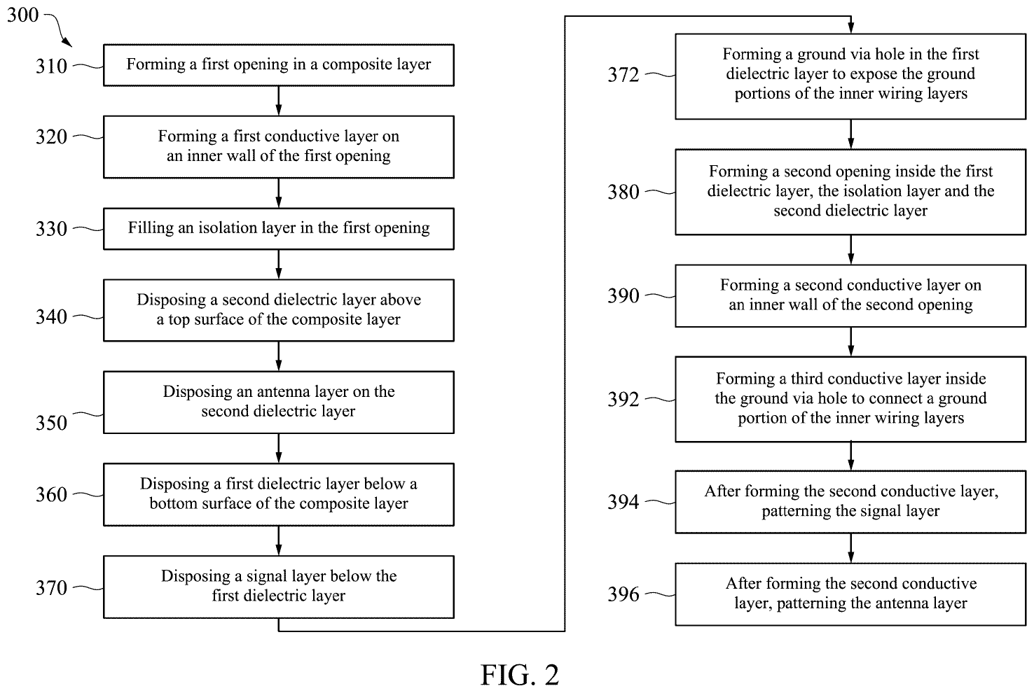

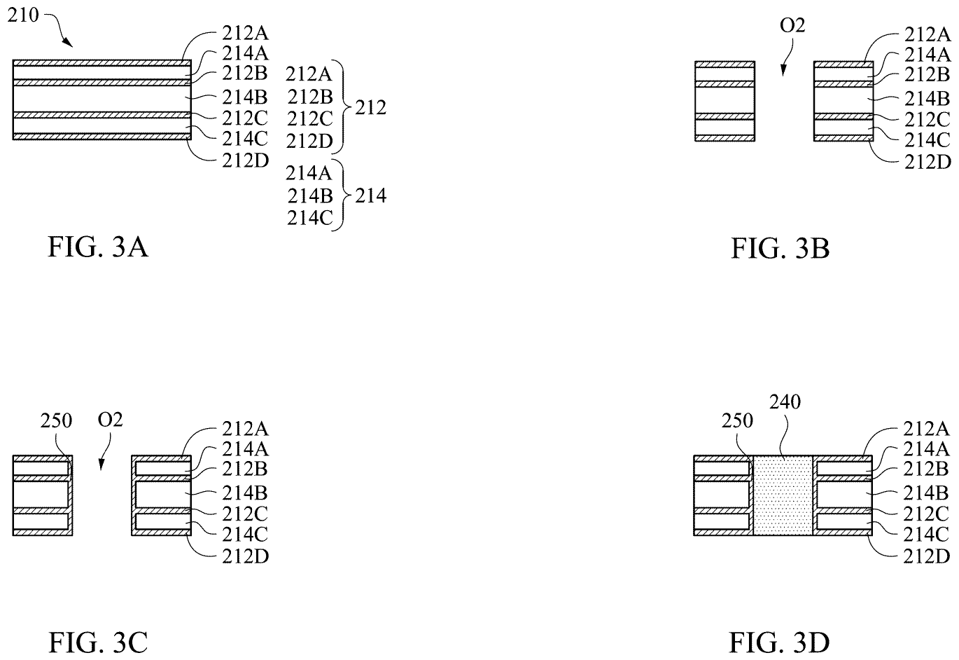

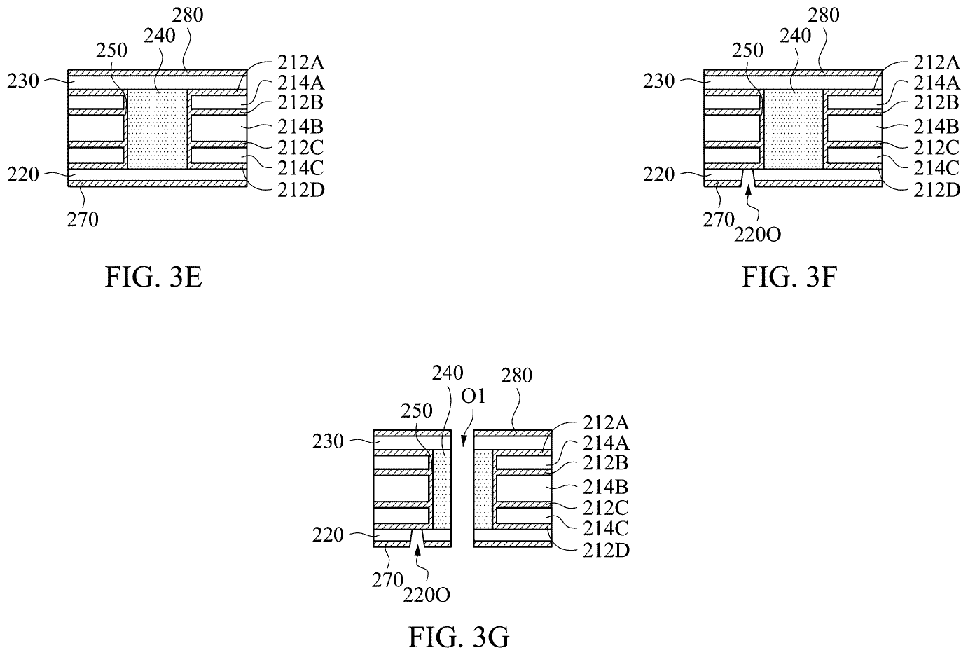

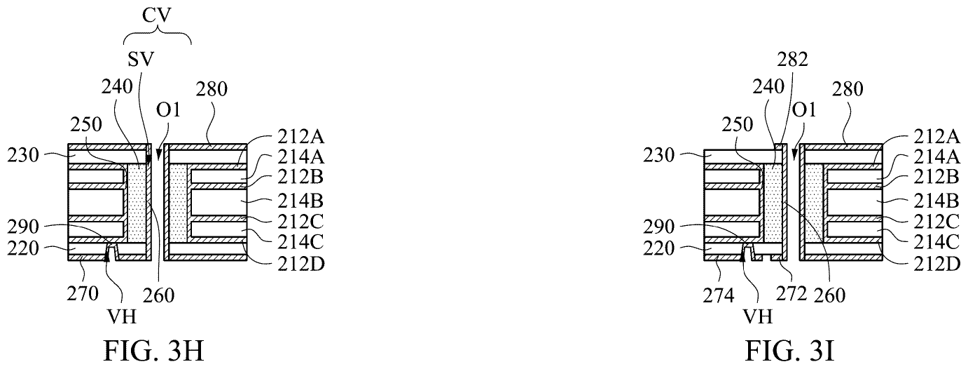

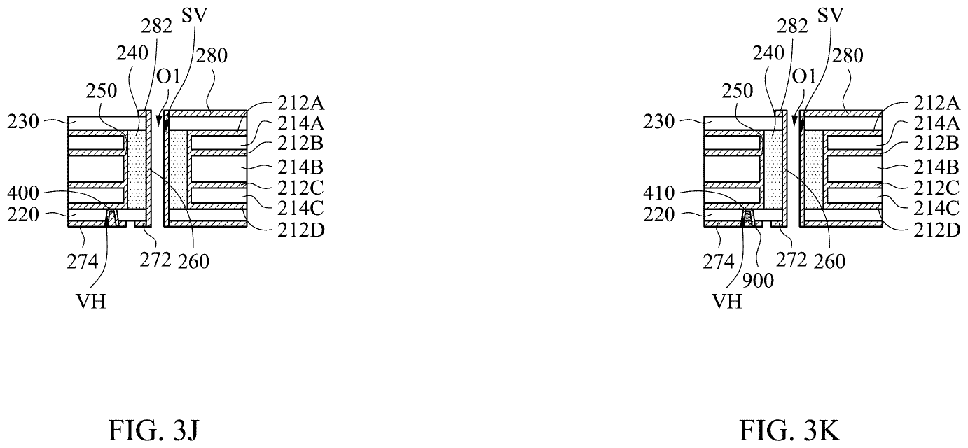

FIG. 2 is a flow chart of a method for manufacturing the circuit board structure 200 in accordance with some embodiments of the present disclosure. FIG. 3A to FIG. 3I are cross-sectional views of a circuit board structure at various stages of the manufacture in accordance with an example of the present disclosure. This description is for illustrative purposes only and is not intended to further limit what is contained in the scope of a subsequent patent application. The method 300 includes steps 310 to 396. It should be appreciated that additional steps may be added before, during, and after steps 310 to 396, and that for another part of the implementation of the method, some of the steps mentioned below may be replaced or cancelled. The order of steps/procedures can be changed.

First, reference is made to FIG. 2 and FIG. 3A. A composite layer 210 is provided. The composite layer 210 includes a plurality of the dielectric layers 214 (such as the dielectric layers 214A, 214B and 214C) and a plurality of inner wiring layers 212 disposed on the top surfaces of the dielectric layers 214 (such as inner wiring layers 212A, 212B, 212C and 212D), and the dielectric layers 214 and inner wiring layers 212 are stacked together by the lamination method.

Following, reference is made to FIG. 2 and FIG. 3B. The method 300 comes to the step 310. An opening O2 is formed in the composite layer 210. For example, an opening process is performed on the middle portion of the composite layer 210, e.g., a mechanical drilling process. The opening O2 penetrates through the plural dielectric layers 214 and the plural inner wiring layers 212, and exposes the side surfaces of the dielectric layers 214.

Following, reference is made to FIG. 2 and FIG. 3B. The method 300 comes to the step 320. The first conductive layer 250 is formed on the inner wall of the opening O2 after forming the opening O2, in which the first conductive layer 250 is electrically connected to the inner wiring layers 212 (such as inner wiring layers 212A, 212B, 212C and 212D). For example, in the present embodiment, the first conductive layer 250 may be formed by an electroplating process. However, it should be noticed that the first conductive layer 250 may be arranged in any appropriate processes without such limitation.

Following, reference is made to FIG. 2 and FIG. 3D. The method 300 comes to the step 330. The isolation layer 240 is filled in the opening O2. For example, in the present embodiment, the isolation layer 240 may be formed by the scrubbing or resin plugging process. However, it should be noticed that the isolation layer 240 may be arranged in any appropriate processes without such limitation.

In some embodiments, after filling the isolation layer 240 in the opening O2, the inner wiring layers 212 may be patterned according to the functional requirements. For example, the inner wiring layers 212 may be patterned by the photolithography process or any appropriate processes. However, it should be noticed that the inner wiring layers 212 may be arranged in any appropriate processes without such limitation.

Following, reference is made to FIG. 2 and FIG. 3E. The method 300 comes to the step 340. The second dielectric layer 230 is disposed on the top surface of the composite layer 210. For example, in the present embodiment, the second dielectric layer 230 may be form by a lamination process. However, it should be noticed that the second dielectric layer 230 may be arranged in any appropriate processes without such limitation.

Following, the method 300 comes to the step 350. The antenna layer 280 is disposed on the second dielectric layer 230. For example, in the present embodiment, the antenna layer 280 may be formed by an electroplating process. However, it should be noticed that the antenna layer 280 may be arranged in any appropriate processes without such limitation.

Following, the method 300 comes to the step 360. The first dielectric layer 220 is disposed on the bottom surface of the composite layer 210. For example, in the present embodiment, the first dielectric layer 220 may be formed by the same process as the second dielectric layer 230, e.g., the lamination process. However, it should be noticed that the first dielectric layer 220 may be arranged in any appropriate processes without such limitation.

Following, the method 300 comes to the step 370. The signal layer 270 is below the first dielectric layer 220. For example, in the present embodiment, the signal layer 270 may be formed by the same process as the antenna layer 280, e.g., the electroplating process. However, it should be noticed that the signal layer 270 may be arranged in any appropriate processes without such limitation.

In some other embodiments, the order of the steps 340, 350, 370 and 360 may be switched. For example, the first dielectric layer 220 may be formed by the lamination process after forming the isolation layer 240. Following, the second dielectric layer 230 may be formed by the same process or any appropriate processes after forming the first dielectric layer 220. Following, the antenna layer 280 and the signal layer 270 may be formed on the second dielectric layer 230 and the first dielectric layer 220.

In some other embodiments, the steps 340, 350, 370 and 360 may be simultaneously performed. For example, after forming the isolation layer 240, the first dielectric layer 220 and the second dielectric layer 230 may be simultaneously formed by the lamination process or any appropriate processes. Following, the antenna layer 280 and the signal layer 270 may be formed on the second dielectric layer 230 and the first dielectric layer 220.

Following, reference is made to FIG. 2 and FIG. 3F. The method 300 comes to the step 372. A ground opening 220O is formed in the first dielectric layer 220 to expose the ground portions of the inner wiring layer 212. For example, in the present embodiment, the ground opening 220O may be formed by a laser process. However, it should be noticed that the ground opening 220O may be arranged in any appropriate processes without such limitation.

Following, reference is made to FIG. 2 and FIG. 3G. The method 300 comes to the step 380. The opening O1 is formed in the first dielectric layer 220, the isolation layer 240 and the second dielectric layer 230. For example, an opening process is performed on the middle portion of the isolation layer 240, e.g., a mechanical drilling process. The opening O1 penetrates through the first dielectric layer 220, the isolation layer 240 and the second dielectric layer 230.

Following, reference is made to FIG. 2 and FIG. 3H. The method 300 comes to the step 390. The second conductive layer 260 is formed on the inner wall of the opening O1, in which the second conductive layer 260 connects the signal layer 270 to the antenna layer 280 to form the signal through via SV, and the second conductive layer 260, the isolation layer 240 and the first conductive layer 250 form the coaxial via CV. For example, the second conductive layer 260 may be formed by an electroplating process. However, it should be noticed that the second conductive layer 260 may be arranged in any appropriate processes without such limitation.

The method 300 comes to the step 392. The third conductive layer 290 is formed in the ground opening 220O, so that the ground via hole VH is formed to be connected to the ground portion of the inner wiring layers 212. For example, in the present embodiment, the third conductive layer 290 may be formed by an electroplating process. However, it should be noticed that the third conductive layer 290 may be arranged in any appropriate processes without such limitation.

In the present embodiment, the steps 390 and 292 may be simultaneously performed. For example, the second conductive layer 260 and the third conductive layer 290 may be formed by the same electroplating process or any appropriate processes after forming the opening O1 and the ground opening 220O. In some other embodiments, the order of the steps 372, 380, 390 and 392 may be switched. For example, after forming the signal through via SV, the ground opening 220O may be formed in the first dielectric layer 220 by the electroplating process, and then the third conductive layer 290 are electroplated to form the ground via hole VH.

Hereafter, reference is made to FIG. 2 and FIG. 3H. The method 300 comes to the step 394. The signal layer 270 is patterned after forming the second conductive layer 260. For example, the signal layer 270 is patterned by a photolithography process or any appropriate processes. However, it should be noticed that the signal layer 270 may be arranged in any appropriate processes without such limitation.

Following, the method 300 comes to the step 396. The antenna layer 280 is patterned after forming the second conductive layer 260 to form the antenna line 282. For example, the antenna layer 280 is patterned by a photolithography process or any appropriate processes. However, it should be noticed that the antenna layer 280 may be arranged in any appropriate processes without such limitation.

In some embodiments, the order of the steps 394 and 396 may be switched or simultaneously performed. For example, the signal layer 270 and the antenna layer 280 may be simultaneously patterned by a photolithography process or any appropriate processes after forming the second conductive layer 260.

FIG. 3J is a cross-sectional view of a circuit board structure 200 in accordance with an example of the present disclosure. The present example is similar to the examples of the FIGS. 3A to 3I. FIG. 3J differs in that: in the present example, the method 300 further includes: form the filler conductive material 400 inside the ground via hole VH. For example, the filler conductive material 400 may be formed inside the ground via hole VH by an electroplating process after forming the third conductive layer 290. However, it should be noticed that the filler conductive material 400 may be arranged in any appropriate processes without such limitation.

FIG. 3K is a cross-sectional view of a circuit board structure 200 in accordance with an example of the present disclosure. The present example is similar to the examples of the FIGS. 3A to 3I. FIG. 3K differs in that: in the present example, the method 300 further includes: form the first filler dielectric material 410 inside the ground via hole VH. For example, the first filler dielectric material 410 may be formed by resin plugging processes after forming the ground via hole VH. However, it should be noticed that the first filler dielectric material 410 may be arranged in any appropriate processes without such limitation.

In some embodiments, the first filler dielectric material 410 may be capped after forming the first filler dielectric material 410. For example, the conductive layer (or the signal layer) 900 may cap the first filler dielectric material 410 by the electroplating process. In some embodiments, the first portion 272 and the second portion 274 of the signal layer 270 and the conductive layer 900 jointly are referred to as a signal layer 270′. However, it should be noticed that the first filler dielectric material 410 may be arranged in any appropriate capping processes without such limitation.

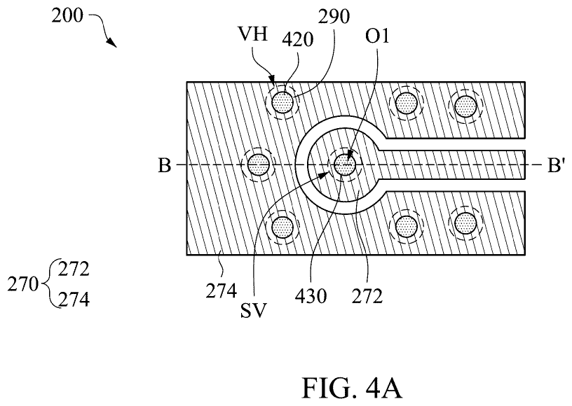

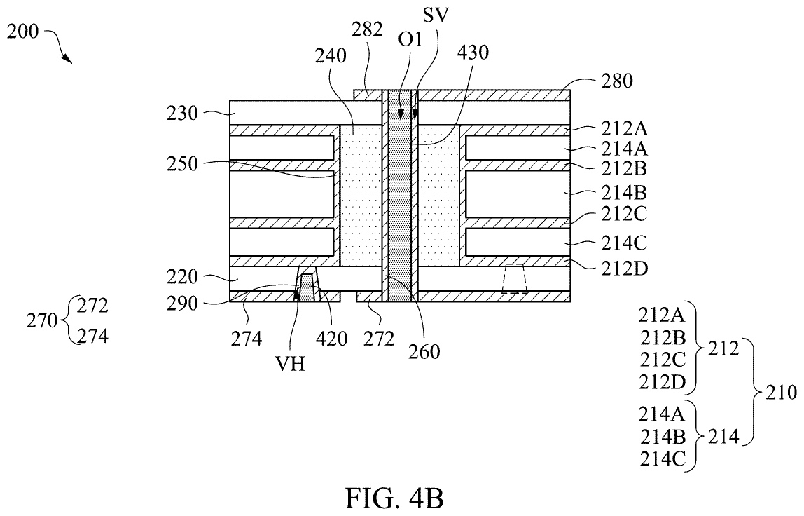

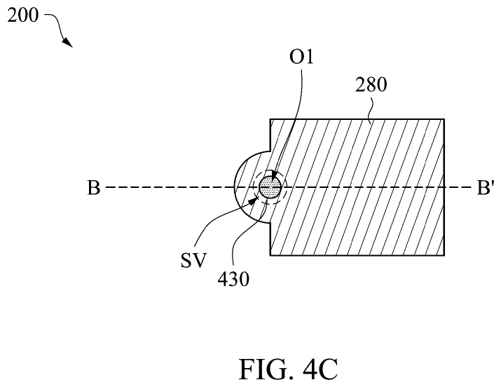

FIG. 4A is an enlarged bottom view of the dotted portion of FIG. 1A in accordance with an example of the present disclosure. FIG. 4B is a cross-sectional view of FIG. 4A taken along the line B-B′. FIG. 4C is a top view of FIG. 4B. Reference is made to FIG. 4A, FIG. 4B and FIG. 4C.

The circuit board structure 200 in the present example is similar to the circuit board structure 200 in FIG. 1A, FIG. 1B and FIG. 1C. The present example differs in that: the circuit board structure 200 in FIG. 4A, FIG. 4B and FIG. 4C further include a third filler dielectric material 430 and a second filler dielectric material 420.

In some embodiments, the third filler dielectric material 430 may be in the opening O1, in which the top surface of the third filler dielectric material 430 is higher than the top surface of the second dielectric layer 230, and the bottom surface of the third filler dielectric material 430 is lower than the bottom surface of the first dielectric layer 220.

In addition, in some embodiments, the second filler dielectric material 420 is in the ground via hole VH. The bottom surface of the second filler dielectric material 420 is coplanar with the second portion 274 of the signal layer 270.

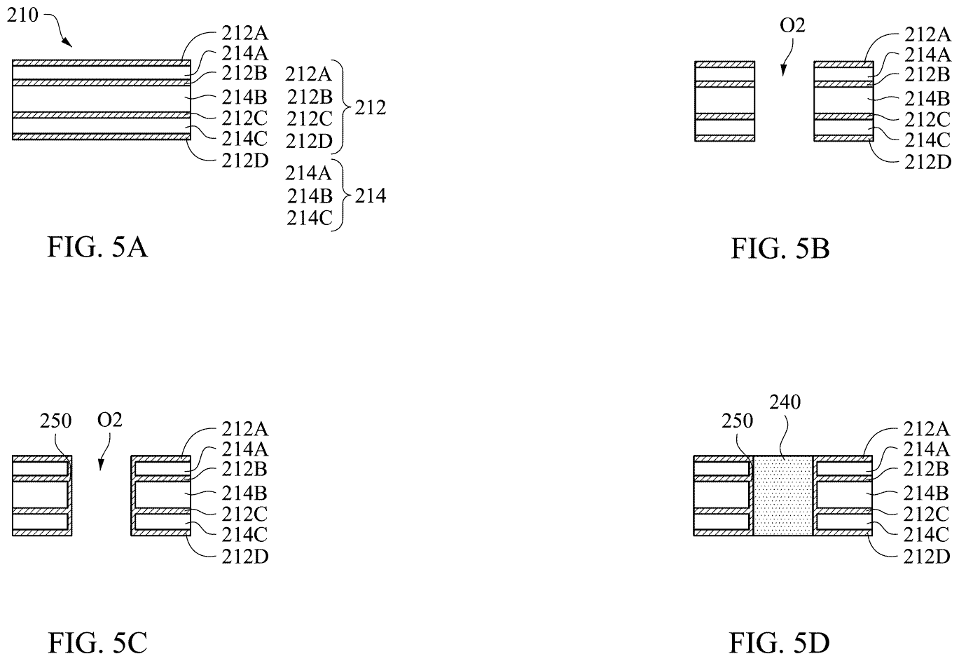

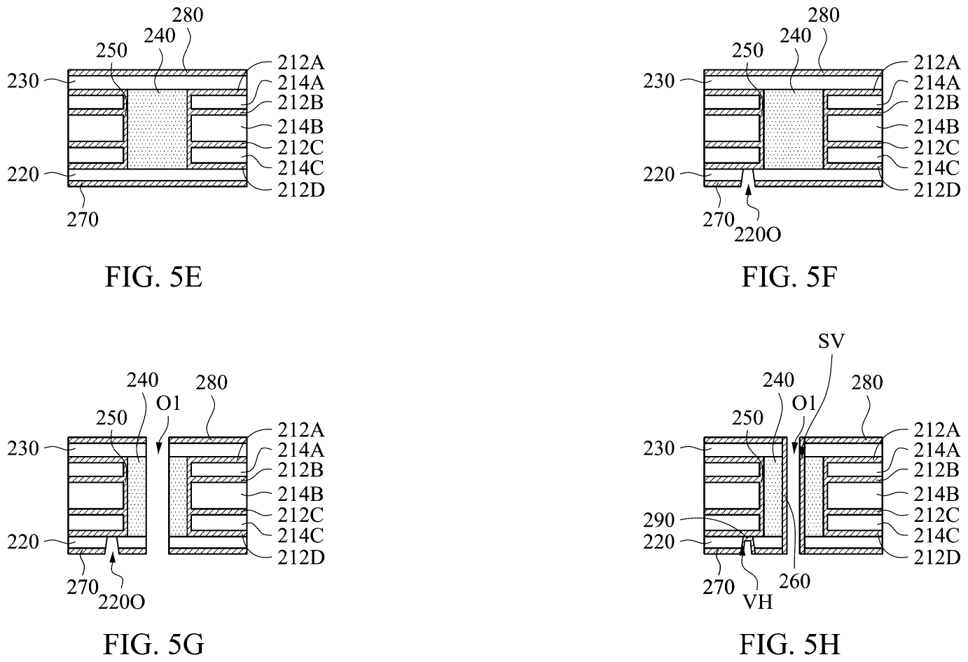

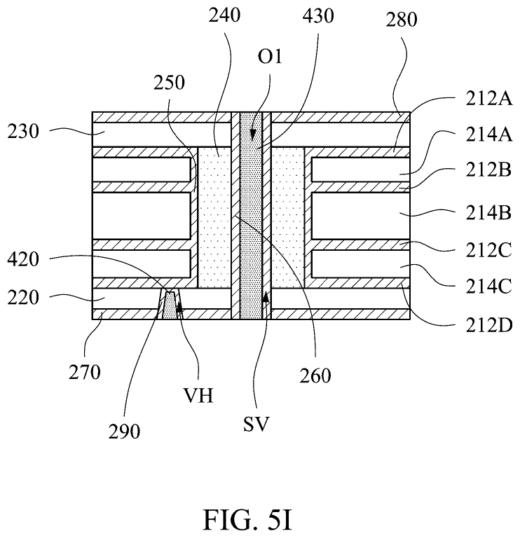

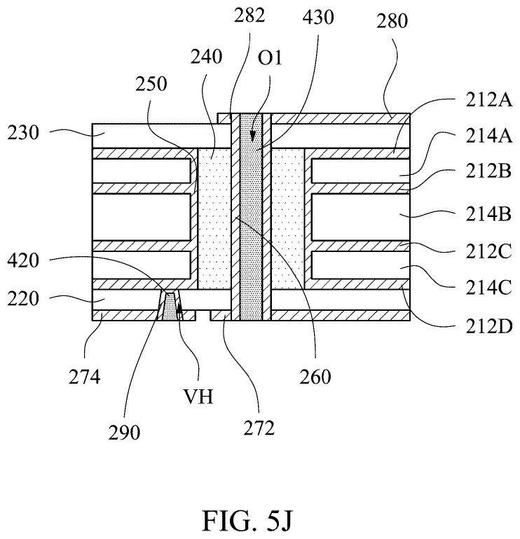

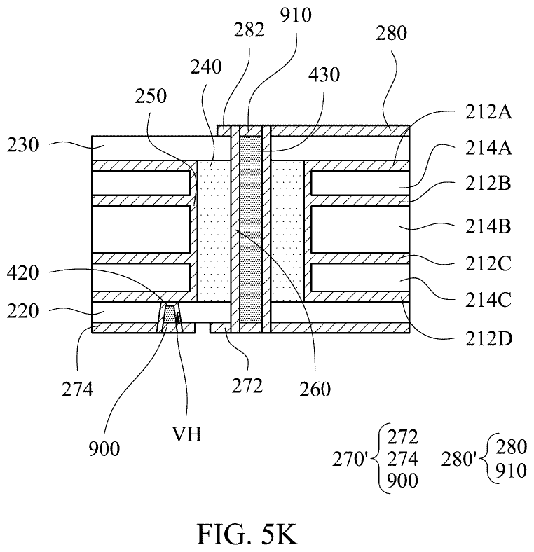

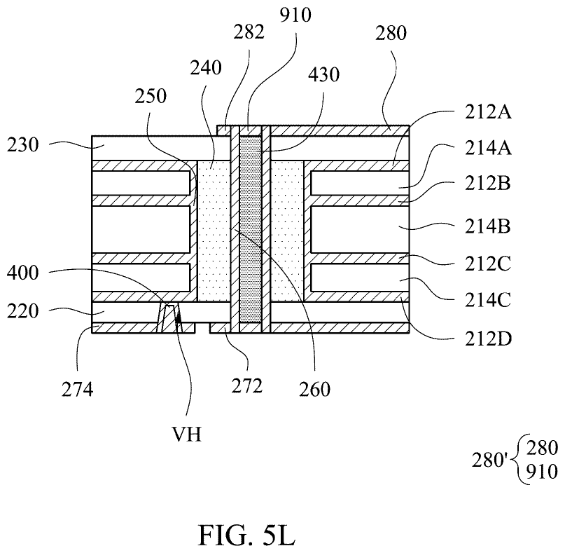

FIG. 5A to FIG. 5J are cross-sectional views of the circuit board structure 200 of FIG. 4B at various stages of the manufacture in accordance with an example of the present disclosure. This description is for illustrative purposes only and is not intended to further limit what is contained in the scope of a subsequent patent application. Reference is made to FIG. 5A to FIG. 5J.

The circuit board structures 200 in FIG. 5A to FIG. 5J are similar to the circuit board structure 200 in FIG. 3A to FIG. 3I. In the present embodiment, in FIG. 5A, a plurality of dielectric layers 214 and a plurality of inner wiring layers 212 are stacked together by a lamination method so that the composite layer 210 is formed. In FIG. 5B, the opening O2 is formed inside the composite layer 210. In FIG. 5C, the first conductive layer 250 is formed on the inner wall of the opening O2 after forming the opening O2, in which the first conductive layer 250 is electrically connected to the inner wiring layers 212. In FIG. 5D, the isolation layer 240 is filled in the opening O2. In FIG. 5E, the second dielectric layer 230 is disposed on the top surface of the composite layer 210. The first dielectric layer 220 is disposed on the bottom surface of the composite layer 210. The signal layer 270 is disposed below the first dielectric layer 220. In FIG. 5F, the ground via hole VH is formed inside the first dielectric layer 220 to expose the ground portion of the inner wiring layers 212. In FIG. 5G, the opening O1 is formed in the first dielectric layer 220, the isolation layer 240 and the second dielectric layer 230. In FIG. 5H, the second conductive layer 260 is formed on the inner wall of the opening O1, in which the second conductive layer 260 connects the signal layer 270 to the antenna layer 280, and the third conductive layer 290 is formed in the ground via hole VH to be connected to the ground portion of the inner wiring layer 212.

The difference between the circuit board structures 200 in FIG. 5A to FIG. 5J and the circuit board structures 200 in FIG. 3A to FIG. 3I is that: in the FIG. 5I, the third filler dielectric material 430 is formed in the opening O1. The second filler dielectric material 420 is formed in the ground via hole VH. In detail, in the present embodiment, the third filler dielectric material 430 and the second filler dielectric material 420 may be formed by the scrubbing or resin plugging process. However, it should be noticed that the third filler dielectric material 430 and the second filler dielectric material 420 may be arranged in any appropriate processes without such limitation.

Furthermore, the third filler dielectric material 430 and the second filler dielectric material 420 may be separately formed. For example, in some embodiments, the second filler dielectric material 420 may be formed in the ground via hole VH by the same process as the third filler dielectric material 430 after forming the third filler dielectric material 430.

Following, in FIG. 5J, the signal layer 270 is patterned to form the first portion 272 and the second portion 274. In the FIG. 5J, the antenna layer 280 is patterned to form the antenna line 282.

FIG. 5K is a cross-sectional view of a circuit board structure 200 in accordance with an example of the present disclosure. The processes described above further include: capping the second filler dielectric material 420 and the third filler dielectric material 430. For example, after forming the third filler dielectric material 430 and the second filler dielectric material 420, the conductive layer (or the signal layer) 900 may cap the bottom ends of the third filler dielectric material 430 and the second filler dielectric material 420 by the electroplating process. The conductive layer (or the signal layer) 910 may cap the top end of the third filler dielectric material 430 by the electroplating process. The first portion 272 and the second portion 274 of the signal layer 270 and the conductive layer 900 jointly are referred to as a signal layer 270′. The antenna layer 280 and the conductive layer 910 jointly referred to as an antenna layer 280′. Thus, the antenna layer 280′ covers the top surface of the third filler dielectric material 430, and the signal layer 270′ covers the bottom surfaces of the third filler dielectric material 430 and the second filler dielectric material 420. However, it should be noticed that the third filler dielectric material 430 and the second filler dielectric material 420 may be arranged in any appropriate capping processes without such limitation.

FIG. 5L is a cross-sectional view of a circuit board structure 200 in accordance with an example of the present disclosure. The present example is similar to the examples in FIG. 5A to FIG. 5J. FIG. 5L differs in that: in the present example, the processes described above further include: form a filler conductive material 400 in the ground via hole VH. For example, the filler conductive material 400 may be formed in the ground via hole VH by an electroplating process. However, it should be noticed that the filler conductive material 400 may be arranged in any appropriate processes without such limitation.

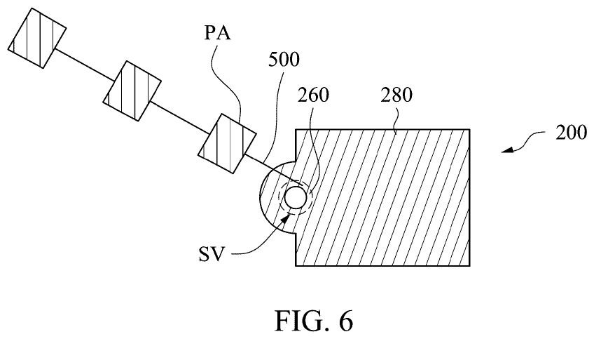

FIG. 6 is a schematic diagram of a circuit board structure 200 horizontally fed in an antenna PA in accordance with some embodiments of the present disclosure. As shown in FIG. 6, the circuit board structure 200 further includes a wire 500 that is on the top end of the second conductive layer 260, and configured to connect to the antenna PA. For example, the antenna layer 280 may be horizontally fed in the antenna PA by the wire 500, in which the wire 500 may overlap with the top end of the second conductive layer 260 so that the second conductive layer 260 is connected to the antenna PA by the antenna layer 280 and the horizontally fed-in wire 500. Thus, signals may be horizontally fed in the antenna PA. In some embodiments of the present disclosure, as examples of the methods of the vertically feeding and horizontally feeding, the circuit board structure 200 may be practically arranged in any appropriate processes without such limitation. In addition, the antenna PA may be any appropriate antennas. In some embodiments, the antenna PA may be a patch antenna.

According to some embodiments of the present disclosure, a circuit board structure and a method for manufacturing the same are provided. The circuit board structure replaces the conventional PTH cross-layer signal line and the conventional antenna feeding method by coaxial vias. The present invention may transmit high frequency and high speed signals to antenna areas of antenna layers by bores. The coaxial via structure may provide transmission lines with well impedance matching, and design well-closed ground paths around vias. In addition to form well high frequency and high speed circuits, this design may separate noises and prevent the energy from dissipations. Furthermore, not all dielectric layers of this design need to use low dielectric constant (DK)/low dissipation factor (DF) materials, thereby significantly lowering the cost of materials.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit board structure, comprising:
a composite layer comprising a plurality of dielectric layers and a plurality of inner wiring layers disposed on surfaces of the dielectric layers;
a first dielectric layer on a bottom surface of the composite layer;
a second dielectric layer on a top surface of the composite layer;
a isolation layer between the first dielectric layer and the second dielectric layer, and adjacent to the composite layer, wherein the isolation layer, the first dielectric layer and the second dielectric layer jointly have an opening extending from a top surface of the second dielectric layer to a bottom surface of the first dielectric layer;
a first conductive layer between the isolation layer and the inner wiring layers, and connected to a ground portion of the inner wiring layers;
a second conductive layer covering an inner well of the opening, wherein the isolation layer separates the second conductive layer from the first conductive layer, and the second conductive layer, the isolation layer and the first conductive layer form a coaxial via;
an antenna layer above the top surface of the second dielectric layer, wherein the antenna layer is connected to a top end of the second conductive layer; and
a signal layer below the bottom surface of the first dielectric layer, wherein a first portion of the signal layer is connected to a bottom end of the second conductive layer.

2. The circuit board structure of claim 1, further comprising:
a first filler dielectric material in the opening.

3. The circuit board structure of claim 2, wherein a top surface of the first filler dielectric material is higher than the top surface of the second dielectric layer, and a bottom surface of the first filler dielectric material is lower than the bottom surface of the first dielectric layer.

4. The circuit board structure of claim 2, wherein the antenna layer covers a top surface of the first filler dielectric material, and the signal layer covers a bottom surface of the first filler dielectric material.

5. The circuit board structure of claim 1, further comprising:
a ground via hole penetrating through the first dielectric layer, wherein the ground via hole is separated from the isolation layer, wherein the ground via hole connects a second portion of the signal layer to the ground portion of the inner wiring layers.

6. The circuit board structure of claim 5, wherein the isolation layer has a first sidewall and a second sidewall opposite each other, the first sidewall of the isolation layer is in contact with the second conductive layer, and the second sidewall of the isolation layer is in contact with the ground portion of the inner wiring layers.

7. The circuit board structure of claim 5, further comprising:
a second filler dielectric material in the ground via hole.

8. The circuit board structure of claim 1, wherein a dielectric constant of the isolation layer is lower than a dielectric constant of the dielectric layers.

9. The circuit board structure of claim 8, wherein the dielectric constant of the isolation layer is between 3 and 3.5.

10. The circuit board structure of claim 1, wherein the antenna layer has an antenna line, and the antenna line overlaps the coaxial via.

11. The circuit board structure of claim 1, further comprising:
a wire on the top end of the second conductive layer, and configured to connect an antenna.

12. A method for manufacturing a circuit board structure, comprising:
forming a first opening in a composite layer, wherein the composite layer comprises a plurality of dielectric layers and a plurality of inner wiring layers disposed on surfaces of the dielectric layers, and the first opening penetrates through the dielectric layers and exposes a side surface of the dielectric layers;
forming a first conductive layer on an inner wall of the first opening, wherein the first conductive layer is electrically connected to the inner wiring layers;
filling a isolation layer in the first opening;
disposing a first dielectric layer below a bottom surface of the composite layer;
disposing a signal layer below the first dielectric layer;
disposing a second dielectric layer above a top surface of the composite layer;
disposing an antenna layer on the second dielectric layer;
forming a second opening inside the first dielectric layer, the isolation layer and the second dielectric layer; and
forming a second conductive layer on an inner wall of the second opening, wherein the second conductive layer connects the signal layer to the antenna layer, and the second conductive layer, the isolation layer and the first conductive layer form a coaxial via.

13. The method of claim 12, further comprising:
after forming the second conductive layer, patterning the signal layer; and
after forming the second conductive layer, patterning the antenna layer.

14. The method of claim 12, further comprising:
forming a first filler dielectric material in the second opening.

15. The method of claim 12, further comprising:
forming a ground via hole inside the first dielectric layer to expose a ground portion of the inner wiring layers; and
forming a third conductive layer inside the ground via hole to connect the ground portion of the inner wiring layers.

16. The method of claim 15, further comprising:
forming a second filler dielectric material inside the ground via hole.
